(19) United States
(12) Patent Application Publication
(10) Pub. No.: US 2007/0181288 A1
(43) Pub. Date: Aug. 9, 2007

(54) COMBINATION OF A HEAT SINK AND A FAN

(76) Inventors: Bing Chen, Shenzhen (CN); Xue-Wen Peng, Shenzhen (CN)

Correspondence Address: NORTH AMERICA INTELLECTUAL PROPERTY CORPORATION, P.O. BOX 506, MERRIFIELD, VA, 22116, US

(21) Appl. No.: 11/307,446

(22) Filed: Feb. 8, 2006

(51) Int. Cl. H05K 7/20

(52) U.S. Cl. 165/80.3; 165/121; 361/697

(57) ABSTRACT

A combination includes an extruded heat sink and a fan secured to the heat sink. The heat sink includes a planar fin and an L-shaped fin. The planar fin and the L-shaped fin commonly define a channel and an entrance to the channel. The fan includes lead wires packed together. The lead wires are allowed to pass through the entrance one by one and to be received in the channel side by side after being turned 90 degrees.

### FIELD OF THE INVENTION

The present invention relates generally to a combination for dissipating heat from an electronic heat-generating component, and more particularly to a combination of a heat sink and a fan mounted onto the heat sink, wherein the heat sink has a fin which is so configured that it can hold lead wires of the fan to the heat sink.

### DESCRIPTION OF RELATED ART

Heat sinks are usually used to remove heat from electronic heat-generating components, such as central processing units (CPUs), VGA chips etc. One type of heat sink comprises a round core and a plurality of fins radially extending from a circumferential periphery of the core. The core is used to absorb heat from the heat-generating component. The fins are used to facilitate dissipation of the heat absorbed by the core. The fins cooperatively define a central recess.

To enhance heat dissipation efficiency of the heat sink, a fan is mounted in the central recess of the heat sink to blow cooling air toward the fins of the heat sink. As we know, the fan has lead wires to supply energy for the fan so that the fan can operate. The lead wires are collected by a collection structure which is used for fixing and protecting the lead wires so that the lead wires will not get loose or engulfed into the fan due to vibration and air flow of the running fan.

In general, the fan further comprises a frame to receive the rotor and stator and blades etc. of the fan. The wire collection structure is arranged on the frame of the fan. The frame comprises four lateral sidewalls and one of the sidewalls defines a longitudinal cutout therein. The cutout extends to a top extremity of the corresponding sidewall to allow the lead wires to enter the cutout. After the lead wires are received in the cutout, a block is wedged into the cutout and keep the lead wires within the cutout. However, the cutout commonly is an irregular void. This increases difficulty of manufacture of the fan. Furthermore, the additional block is an element discrete from the frame. This increases cost of manufacture of the fan. The additional block also prolongs the assembly process of the fan.

What is needed is a combination of a heat sink and a fan wherein the heat sink facilitates to collect lead wires of the fan.

### SUMMARY OF INVENTION

A combination in accordance with a preferred embodiment of the present invention comprises an extruded heat sink and a fan secured to the heat sink. The heat sink comprises a plurality of planar fins and an L-shaped fin. The L-shaped fin and an adjacent planar fin commonly define a channel and an entrance to the channel. The fan comprises lead wires packed together. The lead wires are allowed to pass through the entrance one by one to enter the channel. When passing through the entrance, the wires are vertically oriented so one of the lead wires is located above the other lead wire. Then the lead wires are turned 90 degrees to be horizontally oriented and received in the channel side by side.

Other advantages and novel features will become more apparent from the following detailed description of preferred embodiments when taken in conjunction with the accompanying drawings, in which:

### BRIEF DESCRIPTION OF DRAWINGS

FIG. 1 is an assembled, isometric view of a heat sink and a fan in accordance with a preferred embodiment of the present invention;

FIG. 2 is an exploded, isometric view of FIG. 1; and

FIG. 3 to FIG. 5 are top views, showing procedure of collecting lead wires of the fan to the heat sink.

### DETAILED DESCRIPTION

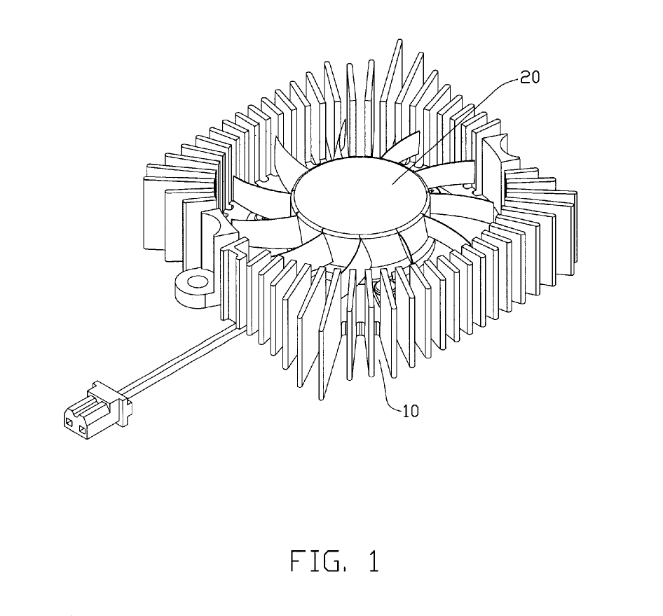

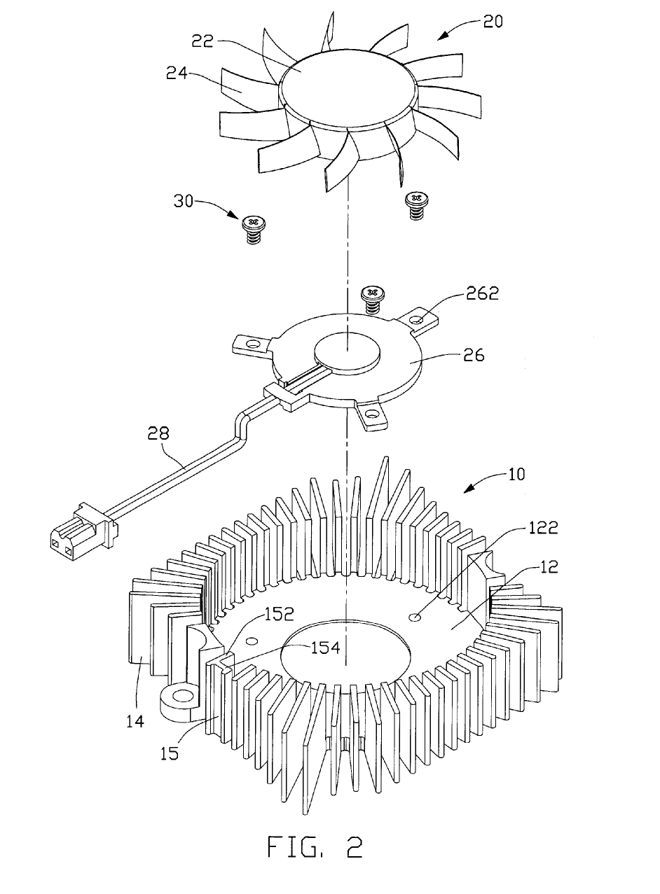

Referring to FIGS. 1-2, a combination in accordance with a preferred embodiment of the invention comprises a heat sink 10 and a fan 20 secured to the heat sink 10 by three screws 30 extending through a holder 26 of the fan 20 and engaging with the heat sink 10.

The fan 20 comprises a hub 22 and a plurality of blades 24 extending radially from a circumferential periphery of the hub 22. The holder 26 supports the hub 22 and the blades 24 thereon. The holder 26 defines three through holes 262 for the screws 30 extending therethrough. At lease two parallel lead wires 28 extend out from the holder 26 for electronically connecting with a power supply (not shown) to provide energy for the fan 20. The lead wires 28 are packed side by side to have a height equal to a diameter of each of the lead wires 28 and a width equal to a sum of the diameters of the lead wires 28.

Referring to FIGS. 1-5, the heat sink 10 is formed by extrusion and comprises a round core 12, a plurality of planar fins 14 integrally extending radially from a circumferential periphery of the round core 12. The core 12 comprises a bottom surface (not shown) to contact an electronic heat-generating component such as a chipset on a VGA card, and a top surface (not labeled) to support the fan 20 thereon. The fins 14 extend upwardly from the periphery of the core 12 to cooperatively define a recess (not labeled) to receive the fan 14 therein. Therefore, the fins 14 surround the fan 20 when the fan 20 is secured to the top surface of the core 12. The core 12 defines three screw holes 122 therein for the screws 30 to threadedly engage therein to secure the fan 20 on the core 12. An additional L-shaped fin 15 is integrally formed with the core 12 by extrusion. The L-shaped fin 15 comprises a main body 152 extending from the core 12 and a flange 154 extending perpendicularly from the main body 152 toward an adjacent fin 14. The flange 15 is located close to a free edge (not labeled) of the main body 152. A channel 16 is defined between the main body 152 of the L-shaped fin 15 and an adjacent fin 14. The channel 16 has a width along the circumferential periphery of the core 12 no less than the sum of diameters of the lead wires 28 so that the lead wires 28 can be accommodated in the channel 28 side by side along the circumferential periphery of the core 12. The flange 154 is separate from the adjacent fin 14 to define an entrance 162 for the channel 16. The entrance 162 allows the channel 16 communicating with an exterior of the channel 16, in addition to two opposite top and bottom opening ends (not labeled) of the channel 16, and allows the lead wires 28 to enter the channel 16 one by one. The entrance 162 has a width which is larger than the diameter of each of the lead wires 28, but smaller than the width of the lead wires 28 (which is equal to the sum of the diameters of the two lead wires 28 in this preferred embodiment). Two ears 18 are symmetrically and integrally extended from the circumferential periphery of the core 12. Each ear 18 defines a securing hole 182 therein for extension of a fastener (not shown) which can be finally engaged with a substrate (not shown) to secure the heat sink 10 to the substrate.

Particularly referring to FIGS. 1-3, the screws 30 extend through the through holes 262 of the fan 20 and threadingly engage in the screw holes 122 of the heat sink 10 so that the fan 20 is secured to the heat sink 10 for enhancing air convection within the heat sink 10.

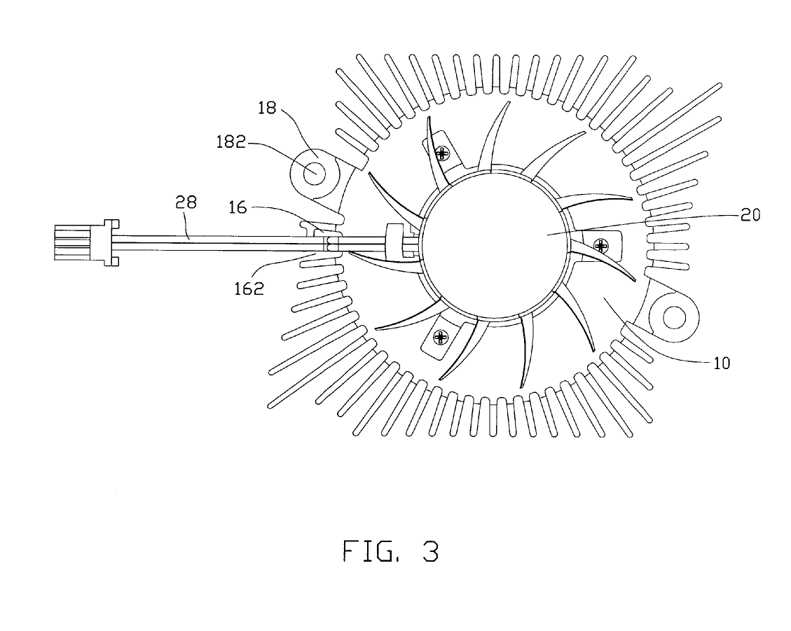

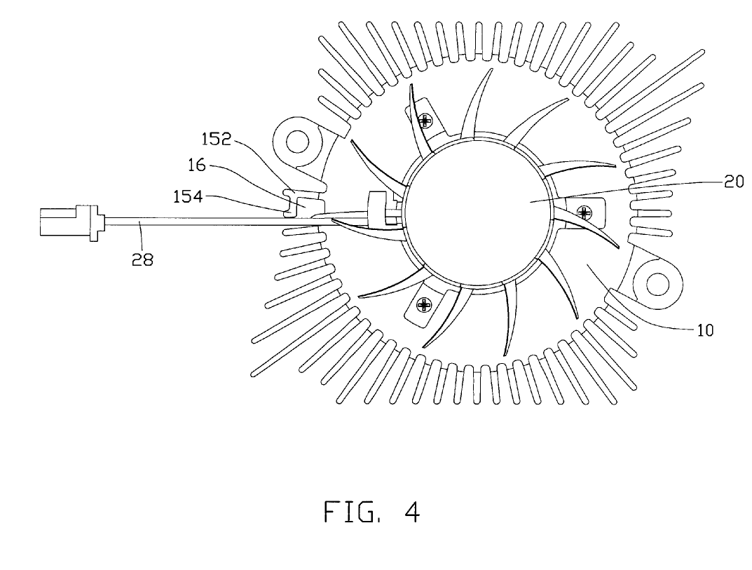

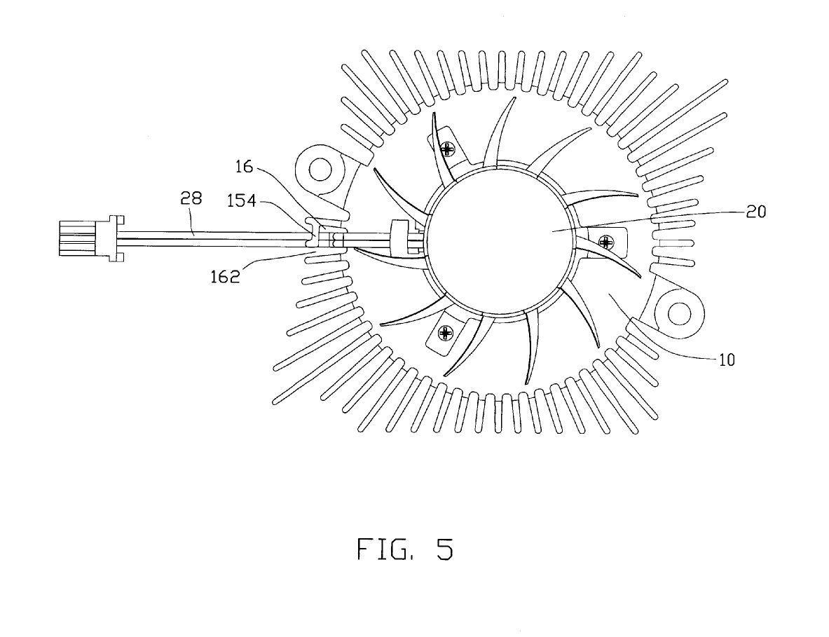

Particularly referring to FIGS. 3-5, the lead wires 28 of the fan 20 are firstly allowed to pass through the entrance 162 of the channel 16 one by one with one lead wire 28 located below the other lead wire 28 (i.e., vertically oriented as shown in FIG. 4) to enter the channel 116. After the lead wires 28 enter the channel 116, they are turned 90 degrees to be received in the channel 16 with one of the lead wires 28 located beside the other lead wire 28 (i.e., horizontally oriented as shown in FIG. 5). The lead wires 28 are arranged side by side along the circumferential periphery of the core 12. Once the lead wires 28 are received in the channel 16, they are prevented by the flange 154 from exiting the channel 16 without being manually manipulated to be turned back to be vertically oriented (see FIG. 4). Therefore, the lead wires 28 of the fan 20 are collected in the channel 16 of the heat sink 10.

In the embodiment of the present invention, the channel 16 receiving the lead wires 28 and the flange 154 preventing the lead wires 28 from exiting the channel 16 are defined when the heat sink 10 is extruded. No additional procedure and no additional element are needed. This efficiently simplifies manufacture and assembly process, and cuts down the cost of achieving the combination of the heat sink 10 and the fan 20.

It is believed that the present embodiments and their advantages will be understood from the foregoing description, and it will be apparent that various changes may be made thereto without departing from the spirit and scope of the invention or sacrificing all of its material advantages, the examples hereinbefore described merely being preferred or exemplary embodiments of the invention.

What is claimed is:

1. A combination comprising:
a fan comprising a hub, a plurality of blades extending outwardly from the hub and lead wires packed side by side; and
a heat sink comprising a core, a planar fin and an L-shaped fin integrally extruded with the core, a channel defined between the L-shaped fin and the planar fin for receiving the lead wires therein side by side along a circumferential periphery of the core, an entrance defined between the L-shaped fin and the planar fin and allowing the lead wires to enter the channel one by one, the entrance having a width which is larger than a diameter of each of the lead wires, but smaller than a sum of the diameters of the lead wires.

2. The combination as claimed in claim 1, wherein the lead wires have a height equal to the diameter of each of the lead wires.

3. The combination as claimed in claim 2, wherein the lead wires have a width equal to the sum of the diameters of the lead wires.

4. The combination as claimed in claim 3, wherein the L-shaped fin comprises a main body extending from the core and a flange perpendicular to the main body for preventing the lead wires from exiting the channel.

5. The combination as claimed in claim 1, wherein the heat sink comprises a plurality of additional planar fins radially extending from the core and surrounding the fan when the fan is secured to the core of the heat sink.

6. The combination as claimed in claim 1, wherein the fan further comprises a holder supporting the hub and the blades thereon and facilitating to secure the fan onto the core of the heat sink.

7. The combination as claimed in claim 6, wherein the holder defines through holes therein, and wherein the core define screw holes therein, screws extend through the through holes and threadingly engage in the screws holes to secure the fan to the core of the heat sink.

8. The combination as claimed in claim 6, wherein the lead wires extend out from the holder adapted for connecting the fan with a power supply.

9. A combination comprising:
an extruded heat sink comprising a planar fin and an L-shaped fin, the planar fin and the L-shaped fin commonly defining a channel and an entrance to the channel; and
a fan secured to the heat sink and comprising lead wires, the lead wires being packed together and being allowed to pass through the entrance one by one to be finally received in the channel side by side after being turned 90 degrees.

10. The combination as claimed in claim 9, wherein the channel has a width no less than a sum of diameters of the lead wires.

11. The combination as claimed in claim 9, wherein the L-shaped fin comprises a main body and a flange extending perpendicularly from the main body toward the planar fin, and wherein the channel is between the main body and the planar fin, and the entrance is between the flange and the planar fin.

12. The combination as claimed in claim 9, wherein the heat sink comprises a round core, and the planar fin and the L-shaped fin are radially extended from the round core.

13. The combination as claimed in claim 12, wherein the heat sink comprises a plurality of additional fins radially extending from the round core, and wherein the fan is secured to the round core and surrounded by the fins of the heat sink.

14. A combination comprising:
a heat sink having a round core and a plurality of fins extending radially outwardly and upwardly from a periphery of the core, the fins cooperatively define a recess above the core, one of the fins cooperating with an adjacent fin to define a channel and an entrance of the channel, the entrance being located outside the channel and having a width smaller than a width of the channel along a circumferential direction of the core; and
a fan received in the recess, the fan having lead wires collected in the channel by passing through the entrance, a diameter of each of the lead wires being smaller than the width of the entrance, a sum of the diameters of the lead wires being larger than the width of the entrance but smaller than the width of the channel.

15. The combination as claimed in claim 14, wherein the one of the fins forms a flange perpendicularly extending from the one of the fins toward the adjacent fin, the entrance is defined between the adjacent fin and the flange.

16. The combination as claimed in claim 15, wherein the flange is located near a free end of the one of the fins.

17. The combination as claimed in claim 14, wherein the lead wires pass through the entrance with one of the lead wires located above the other.

18. The combination as claimed in claim 17, wherein the lead wires are collected in the channel with the one of the lead wires located beside the other.
